(19) United States
(12) Patent Application Publication
(10) Pub. No.: US 2015/0177312 A1
(43) Pub. Date: Jun. 25, 2015

(54) METHOD FOR DETERMINING PN JUNCTION DEPTH

(71) Applicant: Institute of Microelectronics, Chinese Academy of Sciences, Beijing (CN)

(72) Inventors: Jianhui Bu, Beijing (CN); Jinshun Bi, Beijing (CN); Jiajun Luo, Beijing (CN); Zhengsheng Han, Beijing (CN)

(21) Appl. No.: 14/407,170

(22) PCT Filed: Sep. 21, 2012
(86) PCT No.: PCT/CN2012/081780

§ 371 Date: Dec. 11, 2014

(30) Foreign Application Priority Data
Jun. 21, 2012 (CN) 201210212571.2

(51) Int. Cl. G01R 31/26; G01N 27/04

(52) U.S. Cl. CPC G01R 31/2648; G01N 27/041

(57) ABSTRACT

The present invention provides a method for determining PN junction depth comprising: a) measuring a square resistance in a well region; b) forming a junction type field effect transistor in the well region, changing a gate electrode voltage and measuring a source-drain resistance; c) calculating the PN junction depth according to the measured square resistance, source-drain resistance and related process parameters of the junction type field effect transistor. As compared with the prior art, the technical solution in this invention determines the PN junction depth by electrical measurement, is thus simple and feasible, and has better repeatability.

The present application claims priority benefit of Chinese patent application No. 201210212571.2, filed on 21 Jun. 2012, titled “METHOD FOR DETERMINING PN JUNCTION DEPTH”, which is herein incorporated by reference in its entirety.

### FIELD OF THE INVENTION

The present invention relates to the technical field with respect to methods for determining performance parameters of devices, particularly, to a method for determining a PN junction depth.

### BACKGROUND OF THE INVENTION

In manufacturing transistors and integrated circuits by means of plane process, PN junctions are usually manufactured by means of diffusion. Wherein the distance from the surface of the material for a PN junction to the interface of the PN junction is referred to as a PN junction depth. Since the base width, which is the difference between the collector junction depth and emitter junction depth, determines electric parameters of transistors such as amplifying scales and characteristic frequencies, thus the method for determining junction depth becomes a critical technology in the field of semiconductor manufacturing.

Methods for determining junction depth include bevel and stain and SEM (Scanning Electronic Microscopy).

The method for determining PN junction depth by means of bevel and stain process mainly makes stains with a Cu₂O₄ solution.

As the electro-chemical potential of Si is higher than that of Cu, so Si is capable of replacing Cu in the stain solution and forming a red copper-plated layer on the surface of Si. Further, since the electro-chemical potential of N-type Si is higher than that of P-type Si, thus it allows to plater no P region but N region with red copper; in this way, the PN junction can be conspicuously shown.

Steps comprised in the bevel and stain process are as follows:

1. adhering and fixing a wafer, on which baron is redistributed, onto a bevel with wax; grinding a slope on a ground glass, surface of which is required to be smooth and without scratch; then, picking up the wafer and washing it in an acetone solution using ultrasound, then washing it in ethanol using ultrasound, then washing it thoroughly with ion water;

2. putting the wafer, which has been readily cleaned, into a stain solution with the front surface facing up; illuminating the wafer with bulb light for about 30 seconds and observing it closely; picking up and washing the wafer in clean water immediately when the N region is noticed as dyed with a red colour; then drying the wafer with filter paper and then making the measurement. The dyeing time should not be long, otherwise the P region would be dyed in a red colour and consequently the PN junction would not show up.

The shortcomings of this method are the difficulty of controlling the dyeing time, the poor repeatability and complexity involved in the whole process.

Although the method of observing junctions by means of SEM is much simple, this method involves a very high cost.

Accordingly, given the shortcomings of the prior art, it is proposed hereby a method for determining a PN junction depth, which is characterized by simple operation, better repeatability and a low cost.

### SUMMARY OF THE INVENTION

To achieve the above goal, the present invention provides a method for determining a PN junction depth, which comprises:

Step 1: measuring a square resistance in a well region;

Step 2: forming a junction type field effect transistor in the well region, changing a gate electrode voltage and measuring a source-drain resistance;

Step 3: calculating the PN junction depth according to the measured square resistance in a well region, source-drain resistance and related process parameters of the junction type field effect transistor.

As compared to the prior art, the technical solutions provided by the present invention have following advantages:

This method determines the PN junction depth by electrical measurement, and is thus simple and feasible, and has better repeatability.

### BRIEF DESCRIPTION OF THE DRAWINGS

Aforesaid and/or additional characteristics and advantages of the present invention are made more evident and easily understood according to perusal of the following detailed description of exemplary embodiment(s) in conjunction with accompanying drawings, wherein:

FIG. 1 illustrates a flow chart of the method provided by the present invention;

FIG. 2 illustrates a schematic diagram of a JFET layout;

FIG. 3 illustrates a cross-sectional diagram of a JFET layout.

### DETAILED DESCRIPTION OF THE INVENTION

Embodiments of the present invention are to be described here below.

The examples of the embodiments are shown in the drawings. Wherein same or similar reference signs in the drawings denote throughout the same or similar elements. It should be appreciated that the embodiments described below in conjunction with the drawings are illustrative and are provided for explaining the prevent invention only, thus shall not be interpreted as limitations to the present invention. Various embodiments or examples are provided here below to implement different structures of the present invention. To simplify the disclosure of the present invention, the descriptions of components and arrangements of specific examples are given below. Of course, they are illustrative only and not limiting the present invention. Moreover, in the present invention, reference numbers and/or letters may be repeated in different embodiments. Such repetition is for purposes of simplification and clarity, yet does not denote any relationship between respective embodiments and/or arrangements being discussed. Furthermore, the present invention provides various examples for various processes and materials. However, it is obvious for a person of ordinary skill in the art that other processes and/or materials may be alternatively utilized.

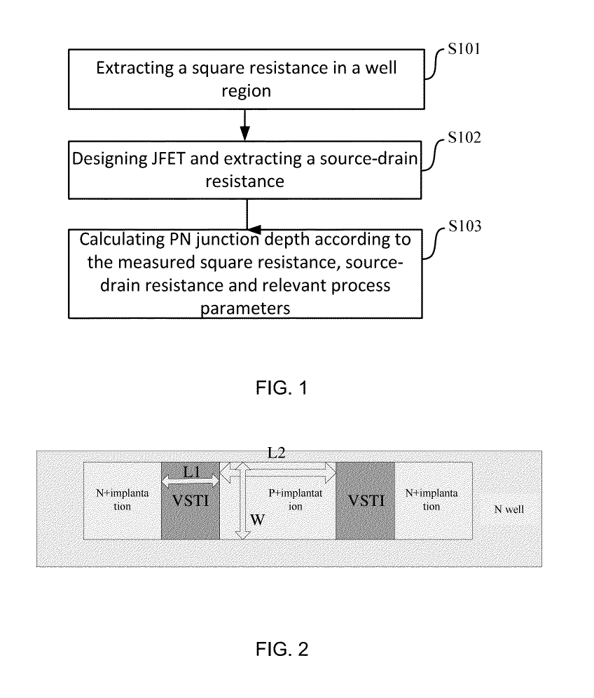

The present invention provides a method for determining PN junction depth. Here below, the method illustrated in FIG. 1 is to be described in detail with an embodiment of the present application in conjunction with FIG. 1 to FIG. 3.

The present embodiment is based on SOI technologies and is intended to exemplify extraction of P⁺N junction depth.

At step S101, extracting a square resistance of a well region; specifically:

The extracting of a square resistance in a well region refers to extracting of a square resistance in a P well in case of an N⁺P junction, and extracting of a square resistance in an N well in case of a P⁺N junction; as it is a P⁺N junction in the present embodiment, so a square resistance of an N well is extracted; it is assumed that the measured square resistance R_{□} is 1000Ω.

At step S102, JFET (Junction type Field Effect Transistor) is designed and source-drain resistance R is extracted. The specific steps are as follows:

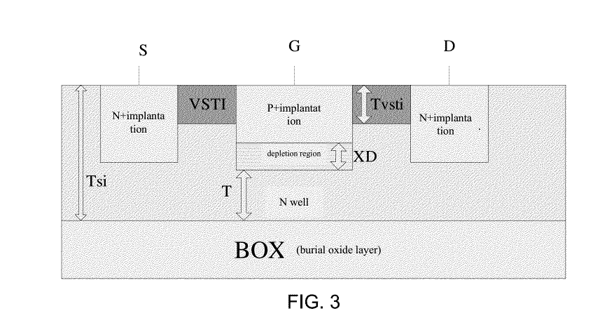

FIG. 2 illustrates the schematic diagram of the designed JFET layout (P+N junction in the present embodiment), which is formed specifically by way of forming a source-drain on N (P) well by implementing N⁺ (P³⁰ ) implantation, forming a gate region in the central area of the source-drain by implementing P⁺ implantation, and isolating the source, the gate and the drain by means of VSTI (Very Shallow Trench Isolation).

Wherein P⁺ implantation width is W, length is L2 and VSTI length is L1; the cross-sectional diagram is illustrated in FIG. 3, wherein the thickness of a Si membrane is Tsi, VSTI depth is Tvsti, depth of the P+N junction depletion region is XD, the boundary of the depletion region from BOX interface is T. in the present embodiment, following related process parameters are assumed:

the thickness of a Si membrane Tsi is 300 nm;

the VSTI depth (Very Shallow Trench Isolation) Tvsti is 180 nm,

P¹ implantation width W is 2 μm, the length thereof L2 is 2 μm,

VSTI length L1 is 0.6 μm.

Nonetheless, a person with an ordinary skill in the art can be aware of the applicability of other parameters.

Next, on the basis of the JFET, resistance from source to drain is extracted when the gate voltage is 0V, aV, bV, respectively; wherein a, b take negative values in case of a P⁺N junction, and a, b take positive values in case of an N⁺P junction; additionally, because a leakage voltage causes change to the resistance from source to drain, thus the leakage voltage should be kept as small as possible at the time of measuring resistance. For example, in the present embodiment, the resistance from source to drain is 10426Ω when the measured gate voltage is 0V; the resistance from source to drain is 14958Ω when the gate voltage is −1V, that is a=−1; the resistance from source to drain is 25473Ω when the gate voltage is −2V, namely, b=−2. During the measurement, the leakage voltage is 0.1V.

At step S103, the PN junction depth is calculated according to the measured square resistance, source-drain resistance and related process parameters of the junction type field effect transistor, which specifically comprises:

calculating T under various gate voltages according to the measured source-drain resistance and square resistance of the well region, as shown in FIG. 2; wherein T refers to the distance from the boundary of the depletion region to the BOX interface; then, according to the difference of T under various gate voltages, calculating the thickness XD (0) of the P⁺N junction depletion region at the time when the gate voltage is 0V; since depletion regions are normally located at the low-doped (N) side, thus the junction depth Xj is approximately equal to:

Tsi−T (0)−XD (0) (1)

wherein, the method for calculating the boundary T (0) of the depletion region from the BOX interface is:

T=(L2/W)R_{□}Tsi/R2 (2)

wherein L2 refers to the P⁺ (N⁺) implantation length, W refers to implantation width, R_{□} refers to the square resistance at the well region extracted at step S101, and R2 refers to the resistance below the depletion region; the method for calculating R2 is:

R2=R−R1 (3)

Wherein R refers to the source-drain resistance extracted at step S102, while R1 refers to the resistance below VSTI; the method for calculating R1 is:

R1=2(L1/W)R_{□}Tsi/(Tsi−Tvsti) (4)

wherein L1 refers to the VSTI length, and Tvsti refers to the VSTI width.

Bringing parameters of the present embodiment into formula (4) can return R1=2(0.6/2)*1000*300/(300−180)=1500Ω

It is assumed the carrier concentration in the depletion region can be negligible, then

R2=(L2/W)R_{□}Tsi/T (5)

Bringing parameters of the present embodiment into formula (5) returns 1000*300/T.

According to the value of R as measured, the calculated value of R1 and the calculating formula for R2, it may obtain T (0)=33.6 nm, T(a)=T (−1)=22.3 nm, T(b)=T (−2)=12.5 nm.

The method for calculating the thickness XD (0) of the P⁺N junction depletion region is resolving following equations:

XD(0)=A*sqrt(VD)

XD(0)=A*sqrt(VD−a)

XD(b)=A*sqrt(VD−b)

XD(a)−XD(0)=T(0)−T(a)

XD(b)−XD(0)=T(0)−T(b) (6)

wherein VD refers to PN junction contact potential difference.

Bringing equations a=−1, b=−2 into the above equations (6) returns:

XD(0)=A*sqrt(VD)

XD(−1)=A*sqrt(VD+1)

XD(−2)=A*sqrt(VD+2)

XD(−1)−XD(0)=T(0)−T(−1)

XD(−2)−XD(0)=T(0)−T(−2)

XD (0) can be obtained by resolving the above equations; wherein T (0), T (−1), T (−2) may be calculated according to the calculation formula for R2; wherein A refers to constants related to the technique.

XD (0)=23.7 nm can be obtained in the present embodiment. Thus, according to formula (1), P⁺N junction depth is (300−23.7−33.6)=242.7 nm in this process.

Accordingly, PN junction depth can be calculated simply by way of changing gate voltage and measuring source-drain resistance according to design parameters of the layout, which has low operating costs and is easy to control.

Although the exemplary embodiments and their advantages have been described herein at length, it should be understood that various alternations, substitutions and modifications may be made to the embodiments without departing from the spirit of the present invention and the scope as defined by the appended claims. As for other examples, it may be easily appreciated by a person of ordinary skill in the art that the order of the process steps may be changed without departing from the scope of the present invention.

In addition, the scope, to which the present invention is applied, is not limited to the process, mechanism, manufacture, material composition, means, methods and steps described in the specific embodiments in the specification. According to the disclosure of the present invention, a person of ordinary skill in the art should readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A method for determining PN junction depth comprising:
a) measuring a square resistance in a well region;
b) forming a junction type field effect transistor in the well region, changing a gate voltage and measuring a source-drain resistance; and
c) calculating the PN junction depth according to the measured square resistance in the well region, source-drain resistance and related process parameters of the junction type field effect transistor.

2. The method of claim 1, wherein step a) of measuring the square resistance in the well region comprises extracting the square resistance in a P well in case of an N⁺P junction, and extracting the square resistance in a N well in case of a P⁺N junction.

3. The method of claim 1, wherein step b) for forming the junction type field effect transistor in the well region comprises:
forming a source-drain region by implementing N⁺ or P⁺ implantation on an N well or a P well;
forming a gate region in a central area of the source-drain region by implementing P⁺ or N⁺ implantation; and
isolating a source region, the gate region and a drain region by means of Very Shallow Trench Isolation (VSTI).

4. The method of claim 3, wherein at the time of forming the junction type field effect transistor, following parameters are obtained:
thickness of Si membrane; VSTI depth and VSTI length; P⁺ or N⁺ implantation width and length.

5. The method of claim 1, wherein, at the step b), changing the gate voltage and measuring source-drain resistance comprises: measuring resistance from source to drain when the gate voltage is 0V, aV, bV; wherein a, b take negative values in case of a P⁺N junction, and a, b take positive values in case of an N⁺P junction.

6. The method of claim 1, wherein, the calculating at the step c) is performed as follows:
junction depth (Xj) is equal to thickness of a Si membrane (Tsi) minus a distance (T) from a depletion region boundary to a burial oxide layer interface of the junction type field effect transistor, minus a thickness (XD) of the PN junction depletion region.

7. The method of claim 6, wherein the distance (T (0)) from the depletion region boundary to a burial oxide layer interface of the junction type field effect transistor at a time when the gate voltage is 0V is computed as follows:
T=(L2/W)R_{□}Tsi/R2
wherein L2 is the P⁺ or N⁺ implantation length, W is the implantation width, R_{□} is the measured square resistance of the well region, Tsi is Si membrane thickness, and R2 is the resistance under the depletion region.

8. The method of claim 7, wherein the resistance R2 under the depletion region is calculated as follows:
R2=R−R1
wherein R is the measured resistance from the source to drain, and R1 is the resistance under the VSTI.

9. The method of claim 8, wherein the resistance R1 under the VSTI is computed as follows:
R1=2(L1/W)R_{□}Tsi/(Tsi−Tvsti)
wherein L1 is a length of the VSTI, and Tvsti is a width of the VSTI.

10. The method of claim 6, wherein, the thickness (XD (0)) of the PN junction depletion region when the gate voltage is 0V is computed on the basis of following equations:
XD(0)=A*sqrt(VD)
XD(a)=A*sqrt(VD−a)
XD(b)=A*sqrt(VD−b)
XD(a)−XD(0)=T(0)−T(a)
XD(b)−XD(0)=T(0)−T(b)
wherein XD (0), XD (a) and XD (b) are respectively the PN junction depletion region thickness when the gate voltage is 0V, aV, bV;
wherein T (0), T (a) and T (b) are respectively the distance from the boundary of the depletion region to the burial oxide layer interface of the junction type field effect transistor when the gate voltage is 0V, aV, bV;
wherein VD is the PN junction contact potential difference; and
wherein A is a process related constant.
